(19) United States
(12) Patent Application Publication
(10) Pub. No.: US 2025/0150082 A1
(43) Pub. Date: May 8, 2025

(54) Low Static Phase Error Charge Pump for PLL Without Calibration

(71) Applicant: Altera Corporation, San Jose, CA (US)

(72) Inventors: Chee Seng Leong, Gelugor (MY); Chun Lee Ler, Bayan Lepas (MY)

(21) Appl. No.: 18/990,950

(22) Filed: Dec. 20, 2024

(51) Int. Cl. H03K 19/17724; H03L 7/099

(52) U.S. Cl. CPC H03K 19/17724; H03L 7/099

(57) ABSTRACT

This disclosure relates to a phase-locked loop (PLL) of a programmable logic device (PLD) (e.g., a field programmable gate array (FPGA)) with reduced static phase error (SPE). The PLD may perform various operations using an internal clock signal generated by the PLL. The PLL may include a charge pump maintaining a phase alignment of the internal clock signal based on a reference clock signal. The charge pump may include a first pair of source follower transistors to reduce the leakage current when the charge pump is deactivated. Alternatively or additionally, the charge pump may include a second pair of source follower transistors to reduce a differential voltage between internal nodes and an output terminal when the charge pump is activated. As such, the charge pump may generate the internal clock signal with reduced SPE and/or phase drift based on including the first and/or second pair of source follower transistors.

### BACKGROUND

The present disclosure relates generally to phase-locked loop (PLL) circuitry for integrated circuit devices, such as programmable logic devices.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

A programmable logic device may perform various processing operations using a clock signal. For example, the programmable logic device may generate the internal clock signals with a clock frequency based on an operating frequency of the processing operations. Clock skew and/or clock phase drifts of the internal clock signals may cause data degradation and may degrade the processing operations of the programmable logic device.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device including a programmable logic device (PLD), in accordance with embodiments of the present disclosure;

FIG. 2 is a block diagram of the integrated circuit device of FIG. 1, in accordance with embodiments of the present disclosure;

FIG. 3 is a block diagram of programmable fabric of the integrated circuit device of FIG. 1, in accordance with embodiments of the present disclosure;

FIG. 4 is a block diagram of a phase-locked loop (PLL) of the PLD of FIGS. 1-3, in accordance with embodiments of the present disclosure;

FIG. 5 is a schematic diagram of a charge pump of the PLL of FIG. 4 including a leakage reduction circuit and a static charge error reduction circuit, in accordance with embodiments of the present disclosure;

FIG. 6 is the schematic diagram of the charge pump of FIG. 5 during a deactivated state of the charge pump, in accordance with embodiments of the present disclosure;

FIG. 7 is the schematic diagram of the charge pump of FIG. 5 during an activated state, in accordance with embodiments of the present disclosure;

FIG. 8 is a block diagram of the charge pump of FIG. 5 having multiple slices, in accordance with embodiments of the present disclosure; and

FIG. 9 is a block diagram of a data processing system including the integrated circuit device of FIG. 1, in accordance with embodiments of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

This disclosure relates to a phase-locked loop (PLL) of a programmable logic device (PLD) (e.g., a field programmable gate array (FPGA)) to generate one or more internal clock signals with reduced static phase error (SPE). The PLD may perform various operations using an internal clock signal. The PLL may generate the internal clock signal. Moreover, the PLL may include a charge pump maintaining a phase alignment of the internal clock signal based on a reference clock signal. If not compensated for, static charges and/or leakage current of the charge pump may increase the SPE or phase discrepancy of the internal clock signal compared to the reference clock signal. The charge pump may include a first pair of source follower transistors to reduce the leakage current when the charge pump is deactivated. Alternatively or additionally, the charge pump may include a second pair of source follower transistors to reduce undesired voltage differences and/or static charge differences between internal nodes and an output terminal of the charge pump when the charge pump is activated.

The charge pump may improve operations of the PLL and/or the PLD by reducing phase errors of the internal clock signal based on including the first pair and/or the second pair of source follower transistors. For example, the charge pump may improve digital signal integrity by reducing a rate of data corruption and/or timing violations of the PLD when processing and/or routing data. Moreover, the PLD may have an increased operation bandwidth and/or may use the internal clock signal having an increased bandwidth. In some embodiments, the charge pump may improve the digital signal integrity of the PLD without consuming substantially more electrical power as opposed to other charge pumps (e.g., including active circuitry and/or calibration circuitry). As such, the charge pump may have a smaller die area, which in turn results in lower power dissipation, compared to other charge pumps.

With the foregoing in mind, FIG. 1 illustrates a block diagram of a system 10 that may implement one or more functionalities, in accordance with embodiments of the present disclosure. For example, a designer may desire to implement functionality, such as the operations of this disclosure, on an integrated circuit device 12 (e.g., a programmable logic device, such as a PLD, an FPGA, or an application specific integrated circuit (ASIC)). In some cases, the designer may specify a high-level program to be implemented, such as an OpenCL® program or SYCL®, which may enable the designer to more efficiently and easily provide programming instructions to configure a set of programmable logic cells for the integrated circuit device 12 without specific knowledge of low-level hardware description languages (e.g., Verilog or VHDL). For example, since OpenCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of one or more logic circuitry 26 on the integrated circuit device 12. The logic circuitry 26 may include circuitry and/or other logic elements and may be configured to implement arithmetic operations, such as addition and multiplication.

The designer may use the design software 14 to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. Additionally or alternatively, the design software 14 may be used to route first data to a portion of the integrated circuit device 12 and route second data, power, and clock signals to a second portion of the integrated circuit device 12. Further, in some embodiments, the system 10 may be implemented without a host program 22 and/or without a separate host program 22. Moreover, in some embodiments, the techniques described herein may be implemented in circuitry as a non-programmable circuit design. Thus, embodiments described herein are intended to be illustrative and not limiting.

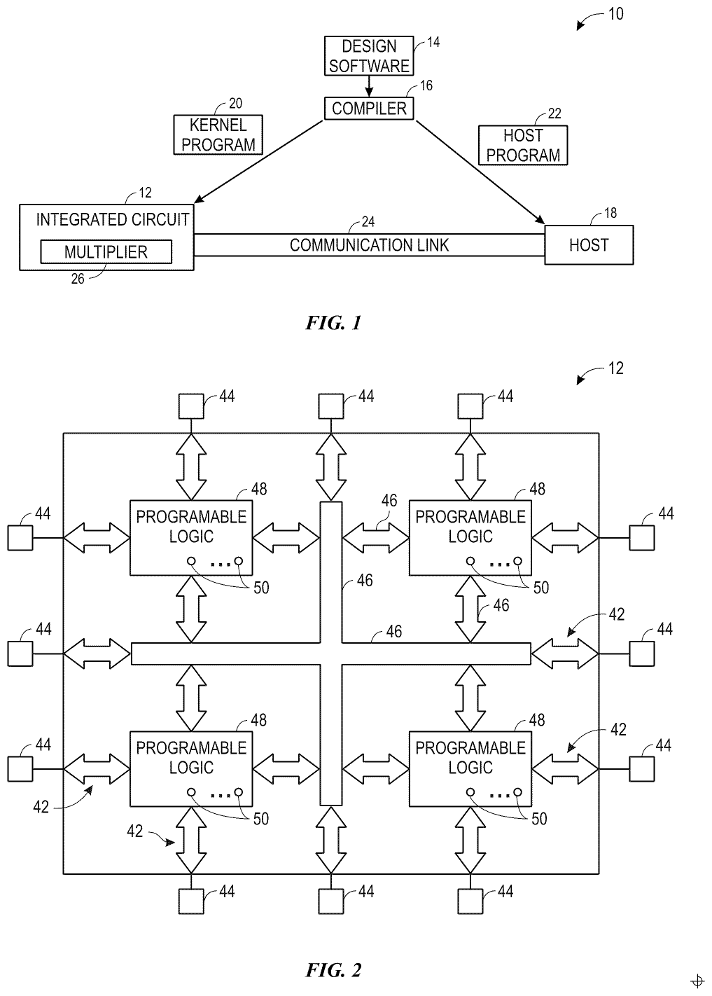

Turning now to a more detailed discussion of the integrated circuit device 12, FIG. 2 is a block diagram of an example of the integrated circuit device 12 as a PLD, such as an FPGA. Further, it should be understood that the integrated circuit device 12 may be any other suitable type of programmable logic device (e.g., a structured ASIC such as eASIC™ by Intel® Corporation and/or application-specific standard product). The integrated circuit device 12 may have input/output circuitry 42 for driving signals off the device and for receiving signals from other devices via input/output pins 44. Interconnection resources 46, such as global and local vertical and horizontal conductive lines and buses, and/or configuration resources (e.g., hardwired couplings, logical couplings not implemented by designer logic), may be used to route signals on integrated circuit device 12. Additionally, interconnection resources 46 may include fixed interconnects (conductive lines) and programmable interconnects (i.e., programmable connections between respective fixed interconnects). For example, the interconnection resources 46 may be used to route signals, such as clock or data signals, through the integrated circuit device 12. Additionally or alternatively, the interconnection resources 46 may be used to route power (e.g., voltage) through the integrated circuit device 12. Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a user, a customer) may (re) program (e.g., (re) configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program the programmable elements 50. In general, programmable elements 50 may be based on any suitable programmable technology, such as fuses, anti-fuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. In some embodiments, the output signals may be applied to the gates of metal-oxide-semiconductor (MOS) transistors within the programmable logic 48.

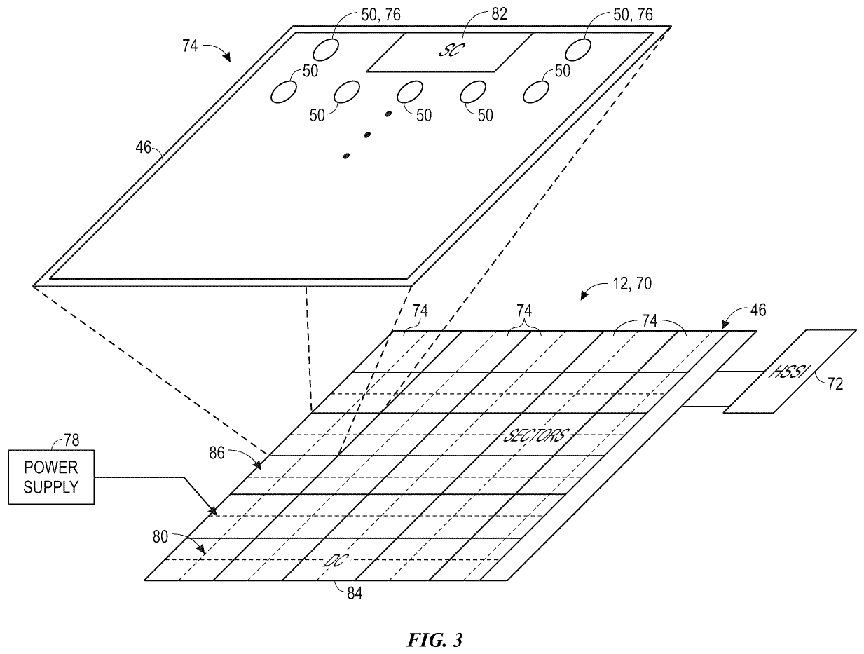

In the example of FIG. 3, the PLD 70 may include transceiver 72 that may include and/or use input/output circuitry, such as input/output circuitry 42 in FIG. 2, for driving signals off the PLD 70 and for receiving signals from other devices. Interconnection resources 46 may be used to route signals, such as clock or data signals, through the PLD 70. The PLD 70 is sectorized, meaning that programmable logic resources may be distributed through a number of discrete programmable logic sectors 74. Programmable logic sectors 74 may include a number of programmable elements 50 having operations defined by configuration memory 76 (e.g., CRAM). A power supply 78 may provide a source of voltage (e.g., supply voltage) and current to a power distribution network (PDN) 80 that distributes electrical power to the various components of the PLD 70. Operating the circuitry of the PLD 70 causes power to be drawn from the power distribution network 80.

There may be any suitable number of programmable logic sectors 74 on the PLD 70. Indeed, while 29 programmable logic sectors 74 are shown here, it should be appreciated that more or fewer may appear in an actual implementation (e.g., in some cases, on the order of 50, 100, 500, 1000, 5000, 10,000, 50,000 or 100,000 sectors or more). Programmable logic sectors 74 may include a sector controller (SC) 82 that controls operation of the programmable logic sectors 74. Sector controllers 82 may be in communication with a device controller (DC) 84.

Sector controllers 82 may accept commands and data from the device controller 84 and may read data from and write data into its configuration memory 76 based on control signals from the device controller 84. In addition to these operations, the sector controller 82 may be augmented with numerous additional capabilities. For example, such capabilities may include locally sequencing reads and writes to implement error detection and correction on the configuration memory 76 and sequencing test control signals to effect various test modes.

The sector controllers 82 and the device controller 84 may be implemented as state machines and/or processors. For example, operations of the sector controllers 82 or the device controller 84 may be implemented as a separate routine in a memory containing a control program. This control program memory may be fixed in a read-only memory (ROM) or stored in a writable memory, such as random-access memory (RAM). The ROM may have a size larger than would be used to store only one copy of each routine. This may allow routines to have multiple variants depending on “modes” the local controller may be placed into. When the control program memory is implemented as RAM, the RAM may be written with new routines to implement new operations and functionality into the programmable logic sectors 74. This may provide usable extensibility in an efficient and easily understood way. This may be useful because new commands could bring about large amounts of local activity within the sector at the expense of only a small amount of communication between the device controller 84 and the sector controllers 82.

Sector controllers 82 thus may communicate with the device controller 84, which may coordinate the operations of the sector controllers 82 and convey commands initiated from outside the PLD 70. To support this communication, the interconnection resources 46 may act as a network between the device controller 84 and sector controllers 82. The interconnection resources 46 may support a wide variety of signals between the device controller 84 and sector controllers 82. In one example, these signals may be transmitted as communication packets.

The use of configuration memory 76 based on RAM technology as described herein is intended to be only one example. Moreover, configuration memory 76 may be distributed (e.g., as RAM cells) throughout the various programmable logic sectors 74 of the PLD 70. The configuration memory 76 may provide a corresponding static control output signal that controls the state of an associated programmable element 50 or programmable component of the interconnection resources 46. The output signals of the configuration memory 76 may be applied to the gates of metal-oxide-semiconductor (MOS) transistors that control the states of the programmable elements 50 or programmable components of the interconnection resources 46.

The programmable elements 50 of the PLD 70 may also include some signal metals (e.g., communication wires) to transfer a signal. In an embodiment, the programmable logic sectors 74 may be provided in the form of vertical routing channels (e.g., interconnects formed along a y-axis of the PLD 70) and horizontal routing channels (e.g., interconnects formed along an x-axis of the PLD 70), and each routing channel may include at least one track to route at least one communication wire. If desired, communication wires may be shorter than the entire length of the routing channel. That is, the communication wire may be shorter than the first die area or the second die area. A length L wire may span L routing channels. As such, a length of four wires in a horizontal routing channel may be referred to as “H4” wires, whereas a length of four wires in a vertical routing channel may be referred to as “V4” wires.

As discussed above, some embodiments of the programmable logic fabric may be configured using indirect configuration techniques. For example, an external host device may communicate configuration data packets to configuration management hardware of the PLD 70. The data packets may be communicated internally using data paths and specific firmware, which are generally customized for communicating the configuration data packets and may be based on particular host device drivers (e.g., for compatibility). Customization may further be associated with specific device tape outs, often resulting in high costs for the specific tape outs and/or reduced scalability of the PLD 70.

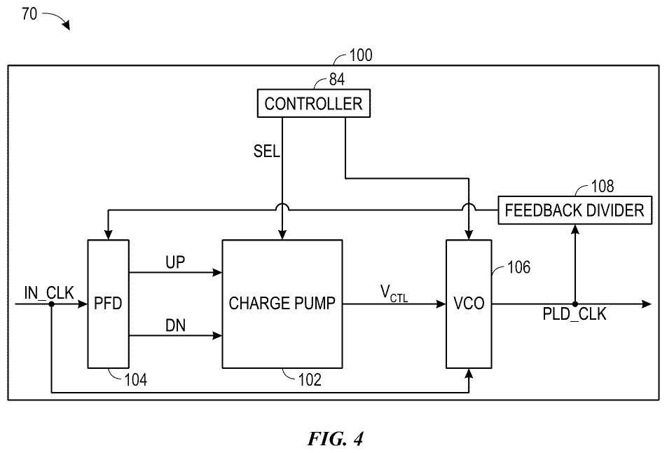

FIG. 4 is a block diagram of a PLL 100 of a PLD 70, in accordance with embodiments of the present disclosure. The PLD 70 may perform various operations using an internal clock signal (PLD_CLK). The PLD 70 may perform one or more operations at a processing rate based on or corresponding to the frequency of the internal clock signal. A PLL 100 of the PLD 70 may generate the internal clock signal based on an input clock signal (IN_CLK). Although a single PLL 100 of the PLD 70 is shown in FIG. 4, it should be appreciated that the PLD 70 may include any viable number of PLLs 100.

The PLL 100 may receive the input clock signal from an external circuit or may include circuitry (e.g., an oscillator, a crystal oscillator) to generate the input clock signal. The input clock signal may have a first clock frequency. Moreover, the PLL 100 may generate the internal clock signal having a second clock frequency based on the input clock signal. For example, in different cases, the PLL 100 may generate the internal clock signal with different clock frequencies and/or clock domains.

The PLL 100 may include various components including a charge pump 102, a phase-frequency detector (PFD) 104, and a voltage-controlled oscillator (VCO) 106 to generate the internal clock signal based on the input clock signal. As mentioned above, the PLD 70 and/or the PLL 100 may include a device controller 84. The device controller 84 may be disposed with or externally to the PLL 100 and/or the PLD 70. In some embodiments, the device controller 84 may be implemented on the programmable logic resources of the PLD 70 discussed above. Alternatively or additionally, the device controller 84 may include any viable processor and/or control circuitry.

The VCO 106 may generate the internal clock signal with the second clock frequency. The second cock frequency may correspond to a desired clock frequency for the PLD 70 to perform the one or more operations. The VCO 106 may generate the internal clock signal by dividing the input clock signal by a divider ratio. In some embodiments, the device controller 84 may provide an indication of the desired clock frequency or the divider ratio to the VCO 106. For example, the VCO 106 may be programmable to generate the internal clock signal with a desired clock frequency based on the divider ratio. Moreover, the VCO 106 may at least partially compensate for the phase lead or phase lag of the internal clock signal based on charge adjustments and/or voltage value adjustments of a control voltage V_{CTL}. The charge pump 102 may adjust the voltage value and/or the charge level of the control voltage V_{CTL} based on the phase lead or phase lag of the internal clock signal, as will be appreciated.

The PFD 104 may be coupled to an output terminal of the VCO 106 to receive a feedback clock signal corresponding to the internal clock signal. Moreover, the PFD 104 may receive the input clock signal (e.g., an instance of the input clock signal). The PFD 104 may compare the internal clock signal with the input clock signal (e.g., a reference clock signal). The PFD 104 may generate an up signal (UP) or a down signal (DN) in response to a phase of the internal clock signal lagging or leading a corresponding phase of the input clock signal, respectively.

The charge pump 102 may activate to substantially align and maintain alignment of a phase of the internal clock signal with the input clock signal (e.g., the reference clock signal). For example, the device controller 84 may generate a selection signal with a first logic value (e.g., a logic high value, a logic low value) to activate at least a portion (e.g., a slice) of the charge pump 102. Moreover, the device controller 84 may not generate the selection signal or may generate the selection signal with the second logic value to deactivate at least a portion (e.g., a slice) of the charge pump 102.

The charge pump 102 may supply electrical charges to increase the control voltage V_{CTL} of the VCO 106 when a phase of the internal clock signal lags a phase of the reference clock signal. The charge pump 102 may supply the electrical charges in response to receiving the up signal UP from the PFD 104. Moreover, the charge pump 102 may sink or draw electrical charges to decrease the control voltage V_{CTL} of the VCO 106 when a phase of the internal clock signal leads a phase of the reference clock signal. The charge pump 102 may sink the electrical charges in response to receiving the down signal DN from the PFD 104. The VCO 106 may at least partially compensate for the phase lead or phase lag of the internal clock signal based on the amount of increase or decrease in the control voltage V_{CTL}.

If not compensated for, in some cases, the charge pump 102 may leak undesired electrical charges to an output terminal when the charge pump 102 is deactivated. The undesired leakage current may increase an SPE and/or an undesired phase drift of the internal clock signal. In some embodiments, the charge pump 102 may include a first pair of source follower transistors to reduce the leakage current. For example, reducing a differential voltage between internal nodes and an output terminal of the charge pump 102 when the charge pump 102 is deactivated may reduce the leakage current. Moreover, the first pair of source follower transistors may reduce the differential voltage between internal nodes (e.g., positive and negative nodes) and the output terminal of the charge pump 102 when the charge pump 102 is deactivated. As such, the first pair of source follower transistors may reduce the leakage current from the internal nodes to the output terminal of the charge pump 102 when the charge pump 102 is deactivated (e.g., idle). Accordingly, the charge pump 102 may improve operations of the PLL 100 and/or the PLD 70 by reducing SPE and/or phase drift of the internal clock signal by including the first pair of source follower transistors.

Moreover, if not compensated for, in some cases, the charge pump 102 may accumulate undesired static charges forming a parasitic capacitor when the charge pump 102 is activated. The undesired static charges may increase the SPE and/or the undesired phase drift of the internal clock signal. In some embodiments, the charge pump 102 may include a second pair of source follower transistors to reduce the voltage differences and/or static charge differences between the internal nodes and the output terminal of the charge pump 102. For example, the charge pump 102 may accumulate the undesired static charges based on a differential voltage between the internal nodes and the output terminal of the charge pump 102. Moreover, the second pair of source follower transistors may reduce the differential voltage between the internal nodes and the output terminal of the charge pump 102 when the charge pump 102 is activated. As such, the second pair of source follower transistors may reduce the differential voltage between the internal nodes and the output terminal of the charge pump 102 when the charge pump 102 is activated. Accordingly, the charge pump 102 may improve operations of the PLL 100 and/or the PLD 70 by reducing SPE and/or phase drift of the internal clock signal by including the second pair of source follower transistors.

With the foregoing in mind, undesired electrical charges of the parasitic capacitors and/or the leakage current may correspond to a higher fraction of the electrical charge consumption of the charge pump 102 at lower frequencies of the internal clock signal. For example, the VCO 106 may divide the input clock signal with an increased divider ratio to generate the internal clock signal with a lower clock frequency. If not compensated for, the undesired electrical charges may cause an increased SPE and/or undesired phase drift in the internal clock signal when the internal clock signal has a lower clock frequency. As mentioned above, the first pair and/or the second pair of source follower transistors may reduce the undesired electrical charges of the charge pump 102. Accordingly, the charge pump 102 may improve operations of the PLL 100 and/or the PLD 70 by increasing the bandwidth of the clock frequency of the internal clock signal.

The charge pump 102 may improve operations of the PLL 100 and/or the PLD 70 by reducing the SPE and/or phase drift of the internal clock signal based on including the first pair and/or the second pair of source follower transistors. For example, the charge pump 102 may improve digital signal integrity and/or reduce a rate of data corruption and/or timing violations of the PLD 70 when processing and/or routing data. Moreover, the PLL 100 and/or the PLD 70 may have an increased operation bandwidth and/or may use the internal clock signal having an increased bandwidth. For example, a frequency bandwidth of the PLL 100 and/or the PLD 70 and/or a processing rate of the PLD 70 may be increased on a lower side of the frequency bandwidth and/or the processing rate below a threshold (e.g., 10 megahertz). In some embodiments, the charge pump 102 may improve the digital signal integrity of the PLD 70 without consuming substantially more electrical power as opposed to other charge pumps (e.g., including active circuitry, calibration circuitry, etc.). As such, the charge pump 102 may have a smaller die area, which in turn results in lower power dissipation, compared to other charge pumps.

In some embodiments, the PLD 70 may include multiple PLLs 100 serially coupled together. For example, a first internal clock signal output from a first PLL 100 may be received as an input clock signal at a second PLL 100, and so on. As such, reducing the SPE and/or phase drift of the first PLL 100 may stabilize the second PLL 100's input clock signal, and so on. In such embodiments, including the first pair and/or the second pair of source follower transistors with the first PLL 100 may reduce the SPE and/or the phase drift of an input clock signal received by the second PLL 100. Accordingly, the second PLL 100 may have an improved phase accuracy and/or reduced SPE and/or phase drift. Additionally, including the first pair and/or the second pair of source follower transistors with the second PLL 100 may further reduce the SPE and/or phase drift of the second PLL 100.

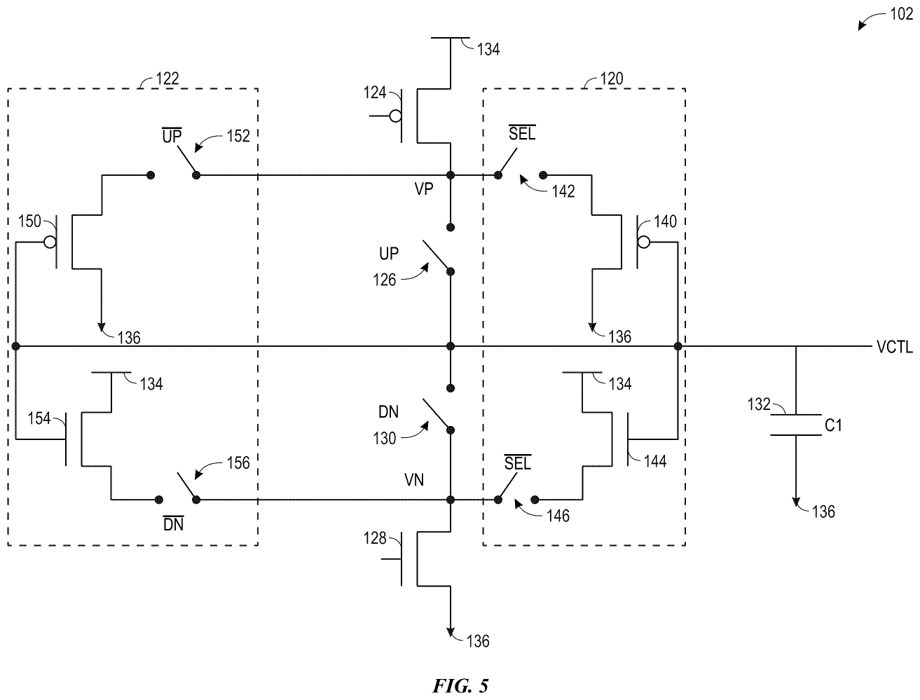

FIG. 5 is a schematic diagram of the charge pump 102 of the PLL 100 including a leakage reduction circuit 120 and a static charge error reduction circuit 122, in accordance with embodiments of the present disclosure. The charge pump 102 may include a first transistor 124, a first switch 126 (UP), a second transistor 128, a second switch 130 (DN), and a filter capacitor 132 (C1). In the depicted embodiment, the first transistor 124 may include a p-channel metal-oxide semiconductor (PMOS) and the second transistor 128 may include an n-channel metal-oxide semiconductor (NMOS). However, it should be appreciated that in alternative or additional embodiments, the first transistor 124 and/or the second transistor 128 may include any other viable transistor or switching circuitry. Moreover, it should be appreciated that the first switch 126 and the second switch 130 may each include any viable transistor or switching circuitry.

A first terminal of the first transistor 124 (e.g., a source terminal) may be coupled to a supply voltage 134 of the PLL 100 and the PLD 70. A second terminal of the first transistor 124 (e.g., a drain terminal) may be coupled to the first switch 126 at a positive node V_{P} (e.g., an internal node) of the charge pump 102. The first switch 126 may receive the up signal UP and the first transistor 124 receives a first bias signal when phases of the internal clock signal are lagging corresponding phases of the input clock signal. As such, the first transistor 124 may couple to the filter capacitor 132 and an output terminal of the charge pump 102 via the first switch 126. The filter capacitor 132 may be coupled to the output terminal of the charge pump 102 and a ground terminal 136. A voltage across the filter capacitor 132 may correspond to the control voltage V_{CTL} of the charge pump 102.

An input terminal (e.g., a gate terminal) of the first transistor 124 may be coupled to the device controller 84 of the PLL 100 and/or the PLD 70. As mentioned above, the device controller 84 of the PLL 100 and/or the PLD 70 may generate the selection signal with a first logic value (e.g., a logic high value, a logic low value) to activate at least a portion (e.g., a slice) of the charge pump 102. The device controller 84 may provide the first bias signal (e.g., a PMOS activation signal, a logic low signal) based on the selection signal having the first logic value to activate the first transistor 124 and the first transistor 124 receiving the first bias signal to switch on. Moreover, the device controller 84 may provide an inverse bias signal (e.g., a logic high signal) based on the selection signal having a second logic value (e.g., an inverse logic value) to deactivate the first transistor 124 and the charge pump 102. In some embodiments, the charge pump 102 may include one or more buffers and/or logic inverters, among other things, to generate the bias signals and/or the inverse bias signals based on the selection signal.

A first terminal of the second transistor 128 (e.g., a source terminal) may be coupled to the ground terminal 136. A second terminal of the second transistor 128 (e.g., a drain terminal) may be coupled to the second switch 130 at a negative node V_{N} (e.g., an internal node) of the charge pump 102. The second switch 130 may receive the down signal DN and the second transistor 128 receives a second bias signal when phases of the internal clock signal are leading corresponding phases of the input clock signal. As such, the second transistor 128 may couple to the filter capacitor 132 and the output terminal of the charge pump 102 via the second switch 130. An input terminal (e.g., a gate terminal) of the second transistor 128 may be coupled to the device controller 84 of the PLL 100 and/or the PLD 70.

The device controller 84 may provide the second bias signal (e.g., an NMOS activation signal, a logic high signal) based on the selection signal having the first logic value to activate the second transistor 128 and the second transistor 128 receiving the second bias signal to switch on. The device controller 84 may provide an inverse bias signal (e.g., the first bias signal, a logic low signal) based on the selection signal having the second logic value to deactivate the second transistor 128 when the charge pump 102 is deactivated. For example, the device controller 84 may switch off or deactivate the first transistor 124 and the second transistor 128 when the charge pump 102 is deactivated. Moreover, the device controller 84 may switch on or activate the first transistor 124 and the second transistor 128 and based on the internal clock signal lagging or leading the input clock signal. In some embodiments, the device controller 84 may receive an indication of the up signal UP and/or the down signal DN, for example, from the PFD 104.

As mentioned above, the PFD 104 may generate the up signal UP and the down signal DN in response to phases of the internal clock signal lagging or leading corresponding phases of the input clock signal. The charge pump 102 may close the first switch 126 in response to the up signal UP. As such, the first transistor 124 may supply electrical charges to the filter capacitor 132 and/or the output terminal of the charge pump 102 when a phase of the internal clock signal lags one or more corresponding phases of the input clock signal. Moreover, the charge pump 102 may close the second switch 130 in response to the down signal DN. As such, the second transistor 128 may sink electrical charges of the filter capacitor 132 and/or the output terminal of the charge pump 102 when a phase of the internal clock signal leads one or more corresponding phases of the input clock signal.

The first switch 126 and the second switch 130 may remain open when phases of the internal clock signal are aligned (e.g., substantially or nearly aligned) with that of the input clock signal. Alternatively or additionally, the first switch 126 and the second switch 130 may remain open when the charge pump 102 is deactivated. For example, the first switch 126 and the second switch 130 may remain open based on a lack of the up signal UP and down signal DN from the PFD 104 discussed above.

The leakage reduction circuit 120 may include a third transistor 140 (e.g., a first source follower transistor), a third switch 142, a fourth transistor 144 (e.g., a second source follower transistor), and a fourth switch 146. In the depicted embodiment, the third transistor 140 may include a PMOS and the fourth transistor 144 may include an NMOS. It should be appreciated that in alternative or additional embodiments, the third transistor 140 and/or the fourth transistor 144 may include any other viable transistor or switching circuitry. Moreover, it should be appreciated that the third switch 142 and the fourth switch 146 may each include any viable transistor or switching circuitry.

A first terminal (e.g., a source terminal) of the third transistor 140 may be coupled to the third switch 142. The first terminal of the third transistor 140 may couple to the first transistor 124 and a first side of the first switch 126 at the positive node V_{P} via the third switch 142. The third switch 142 may receive an inverse of the selection signal (S̅E̅L̅). As such, the third switch 142 may open in response to the charge pump 102 being activated and/or the selection signal having the first logic value. A second terminal (e.g., a drain terminal) of the third transistor 140 may be coupled to the ground terminal 136. An input terminal (e.g., a gate terminal) of the third transistor 140 may be coupled to second sides of the first switch 126 and the second switch 130, the filter capacitor 132, and the output terminal of the charge pump 102.

A first terminal (e.g., a source terminal) of the fourth transistor 144 may be coupled to the fourth switch 146. The first terminal of the fourth transistor 144 may couple to the second transistor 128 and a first side of the second switch 130 at the negative node V_{N} via the fourth switch 146. The fourth switch 146 may receive the inverse of the selection signal (S̅E̅L̅). As such, the fourth switch 146 may open in response to the charge pump 102 being activated and/or the selection signal having the first logic value. A second terminal (e.g., a drain terminal) of the fourth transistor 144 may be coupled to the supply voltage 134. An input terminal (e.g., a gate terminal) of the fourth transistor 144 may be coupled to the second sides of the first switch 126 and the second switch 130, the input terminal of the third transistor 140, the filter capacitor 132, and the output terminal of the charge pump 102.

The static charge error reduction circuit 122 may include a fifth transistor 150 (e.g., a third source follower transistor), a fifth switch 152, a sixth transistor 154 (e.g., a fourth source follower transistor), and a sixth switch 156. In the depicted embodiment, the fifth transistor 150 may include a PMOS and the sixth transistor 154 may include an NMOS. It should be appreciated that in alternative or additional embodiments, the fifth transistor 150 and/or the sixth transistor 154 may include any other viable transistor or switching circuitry. Moreover, it should be appreciated that the fifth switch 152 and the sixth switch 156 may each include any viable transistor or switching circuitry.

A first terminal (e.g., a source terminal) of the fifth transistor 150 may be coupled to the fifth switch 152. The first terminal of the fifth transistor 150 may couple to the first transistor 124, the third switch 142, and the first side of the first switch 126 at the positive node V_{P} via the fifth switch 152. The fifth switch 152 may receive an inverse of the up signal (U̅P̅). A second terminal (e.g., a drain terminal) of the fifth transistor 150 may be coupled to the ground terminal 136. An input terminal (e.g., a gate terminal) of the fifth transistor 150 may be coupled to the second sides of the first switch 126 and the second switch 130, the filter capacitor 132, the output terminal of the charge pump 102, and the input terminals of the third transistor 140 and the fourth transistor 144.

A first terminal (e.g., a source terminal) of the sixth transistor 154 may be coupled to the sixth switch 156. The first terminal of the sixth transistor 154 may couple to the second transistor 128, the fourth switch 146, and the first side of the second switch 130 at the negative node V_{N} via the sixth switch 156. The sixth switch 156 may receive an inverse of the down signal (DN). A second terminal (e.g., a drain terminal) of the sixth transistor 154 may be coupled to the supply voltage 134. An input terminal (e.g., a gate terminal) of the sixth transistor 154 may be coupled to the second sides of the first switch 126 and the second switch 130, the filter capacitor 132, the output terminal of the charge pump 102, and the input terminals of the third transistor 140, the fourth transistor 144, and the fifth transistor 150.

In the depicted embodiment, the transistors 124, 140, and 150 may each include a PMOS. Moreover, the transistors 128, 144, and 154 may each include an NMOS. In alternative or additional embodiments, the transistors 124, 140, and 150 may each include an NMOS and the transistors 128, 144, and 154 may each include a PMOS. In such embodiments, the first terminal of the first transistor 124 may be coupled to the ground terminal 136, the first terminal of the second transistor 128 may be coupled to the supply voltage 134, the second terminals of the transistors 140 and 150 may be coupled to the supply voltage 134, and the second terminals of the transistors 144 and 154 may be coupled to the ground terminal 136. In alternative or additional embodiments, the transistors 124, 140, 150, 124, 140, and/or 150 may each include any other viable transistor or switching circuitry.

In the depicted embodiment, the transistors 140 and 144 of the leakage reduction circuit 120 may buffer an input voltage of the respective input terminal when activated. In some embodiments, the third transistor 140 and/or the fourth transistor 144 may have a relatively thin gate design compared to that of other transistors (e.g., voltage gain transistors) based on being coupled as voltage buffers. As such, the charge pump 102 may have a smaller die area and lower power dissipation when including a leakage reduction circuit compared to other charge pumps having other leakage reduction circuits (e.g., active leakage reduction circuits).

Likewise, the transistors 150 and 154 of the static charge error reduction circuit 122 may buffer an input voltage of the respective input terminal when activated. In some embodiments, the fifth transistor 150 and/or the sixth transistor 154 may have a relatively thin gate design compared to that of other transistors (e.g., voltage gain transistors) based on being coupled as voltage buffers. As such, the charge pump 102 may have a smaller die area and lower power dissipation when including a static charge error reduction circuit compared to other charge pumps having other static charge error reduction circuits (e.g., active static charge error reduction circuits).

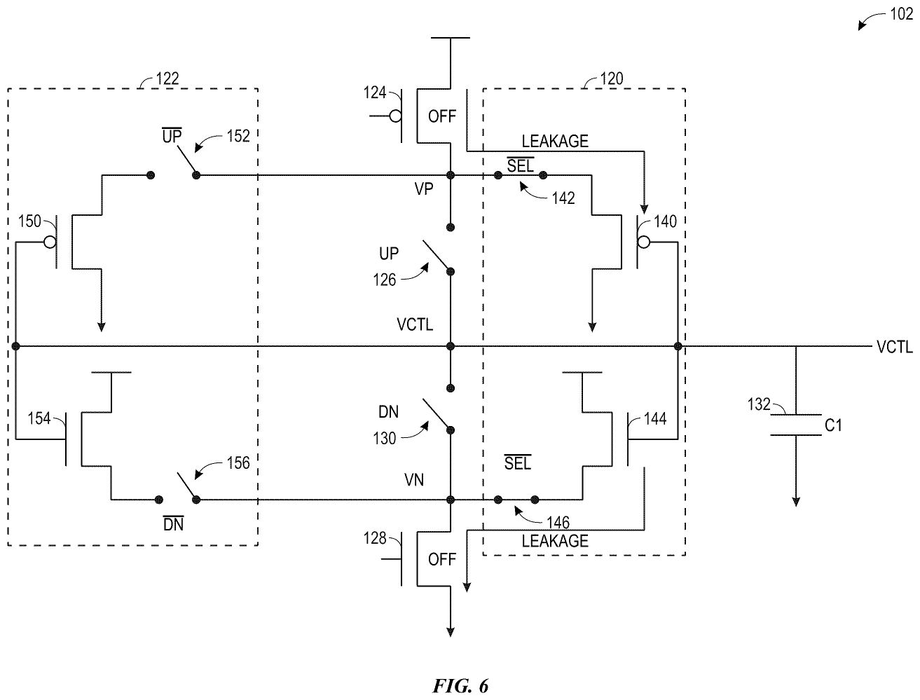

FIG. 6 is the schematic diagram of the charge pump 102 during a deactivated state, in accordance with embodiments of the present disclosure. In some cases, the device controller 84 may generate the selection signal with a second logic value discussed above (or may not generate the selection signal) to deactivate at least a portion (e.g., a slice) of the charge pump 102. In such cases, the first transistor 124 and the second transistor 128 may remain and/or switch off (e.g., deactivated).

For example, the first transistor 124 may receive a first bias signal (e.g., a PMOS deactivation signal, a logic high signal) when the charge pump 102 is deactivated. Moreover, the second transistor 128 may receive a second bias signal (e.g., an NMOS deactivation signal, a logic low signal) when the charge pump 102 is deactivated. In some cases, the first bias signal may be inverse of the second bias signal. In some embodiments, the device controller 84 may generate the first bias signal and the second bias signal. In alternative or additional embodiments, the charge pump 102 may include circuitry (e.g., resources of the PLD 70 and/or the integrated circuit device 12, logic circuitry 26) to generate the first bias signal and the second bias signal based on the selection signal.

In some embodiments, the PFD 104 may remove the up signal UP, the down signal DN, the inverse of the up signal U̅P̅, and the inverse of the down signal D̅N̅ when the charge pump 102 is deactivated. In alternative or additional embodiments, the charge pump 102 may remove the up signal UP, the down signal DN, the inverse of the up signal U̅P̅, and the inverse of the down signal D̅N̅ in response to the charge pump 102 being deactivated. For example, the charge pump 102 may include circuitry (e.g., resources of the PLD 70 and/or the integrated circuit device 12, logic circuitry 26) to remove the aforementioned signals based on the selection signal having the second logic value. Accordingly, the charge pump 102 may open the first switch 126, the second switch 130, the fifth switch 152, and the sixth switch 156 when the charge pump 102 is deactivated. Moreover, the static charge error reduction circuit 122 may be deactivated.

If not compensated for, the voltage values at the positive node V_{P} and the negative node V_{N} of the charge pump 102 may remain at or switch to zero volts, near zero volts, near a ground voltage value of the ground terminal 136, among other possibilities. In some cases, a differential voltage between the positive node V_{P} and the output terminal of the charge pump 102 and/or between the output terminal and the negative node V_{N} may be above a threshold. In the depicted embodiment, the leakage reduction circuit 120 may reduce a first differential voltage between the positive node V_{P} and the output terminal of the charge pump 102 when the charge pump 102 is deactivated. Alternatively or additionally, the leakage reduction circuit 120 may reduce a second differential voltage between the output terminal and the negative node V_{N}.

The third switch 142 and the fourth switch 146 may receive an inverse of the selection signal (S̅E̅L̅). As such, the third switch 142 and the fourth switch 146 may close in response to the charge pump 102 being deactivated and/or the selection signal having the second logic value. The third transistor 140 may activate (e.g., switch on) and at least partially couple the positive node V_{P} of the charge pump 102 to the filter capacitor 132 and the output terminal of the charge pump 102. The fourth transistor 144 may activate (e.g., switch on) and at least partially couple the negative node V_{N} of the charge pump 102 to the filter capacitor 132 and the output terminal of the charge pump 102. Accordingly, the leakage reduction circuit 120 may become activated (or remain activated) when the charge pump 102 is deactivated.

The third transistor 140 and the fourth transistor 144 may have high input impedances above a high impedance threshold at the respective input terminals when activated. Moreover, the third transistor 140 and the fourth transistor 144 may have low output impedances below a low impedance threshold at the respective first terminals when activated. In some embodiments, the voltage of the first terminal of the first transistor 124 at the positive node V_{P} may be equal to (e.g., nearly equal to) a combination of a first threshold voltage V_{TP1} (e.g., a source-to-gate voltage) of the third transistor 140 and the control voltage V_{CTL} of the filter capacitor 132 at the output terminal:

$${V}_{P} ∼ = {V}_{CTL} + {V}_{TP 1} \qquad ( Equation 1 )$$

In some cases, a voltage value of the first threshold voltage V_{TP1} may be smaller (e.g., substantially smaller, relatively smaller) than the control voltage V_{CTL}. As such, the third transistor 140 may reduce the first differential voltage between the positive node V_{P} and the output terminal of the charge pump 102 when the charge pump 102 is deactivated. Moreover, the leakage reduction circuit 120 may reduce the leakage current from the positive node V_{P} to the output terminal of the charge pump 102 based on reducing the first differential voltage when the charge pump 102 is deactivated. As mentioned above, the VCO 106 may at least partially compensate for the phase lead or phase lag of the internal clock signal based on the control voltage V_{CTL}. Accordingly, the charge pump 102 may improve operations of the PLL 100 and/or the PLD 70 by reducing SPE and/or phase drift of the internal clock signal by including the third transistor 140.

In some embodiments, the voltage of the first terminal of the second transistor 128 at the negative node V_{N} may be equal to (e.g., nearly equal to) a combination of a second threshold voltage V_{TP2} (e.g., a gate-to-source voltage) of the fourth transistor 144 and the control voltage V_{CTL} of the filter capacitor 132 at the output terminal:

$${V}_{N} ∼ = {V}_{CTL} - {V}_{TP 2} \qquad ( Equation 2 )$$

In some cases, a voltage value of the second threshold voltage V_{TP2} may be smaller (e.g., substantially smaller) than the control voltage V_{CTL}. As such, the fourth transistor 144 may reduce the second differential voltage between the negative node V_{N} and the output terminal of the charge pump 102 when the charge pump 102 is deactivated. Moreover, the leakage reduction circuit 120 may reduce the leakage current from the negative node V_{N} to the output terminal of the charge pump 102 based reducing the second differential voltage when the charge pump 102 is deactivated. Furthermore, the VCO 106 may at least partially compensate for the phase lead or phase lag of the internal clock signal based on the control voltage V_{CTL}. Accordingly, the charge pump 102 may improve operations of the PLL 100 and/or the PLD 70 by reducing SPE and/or phase drift of the internal clock signal by including the fourth transistor 144.

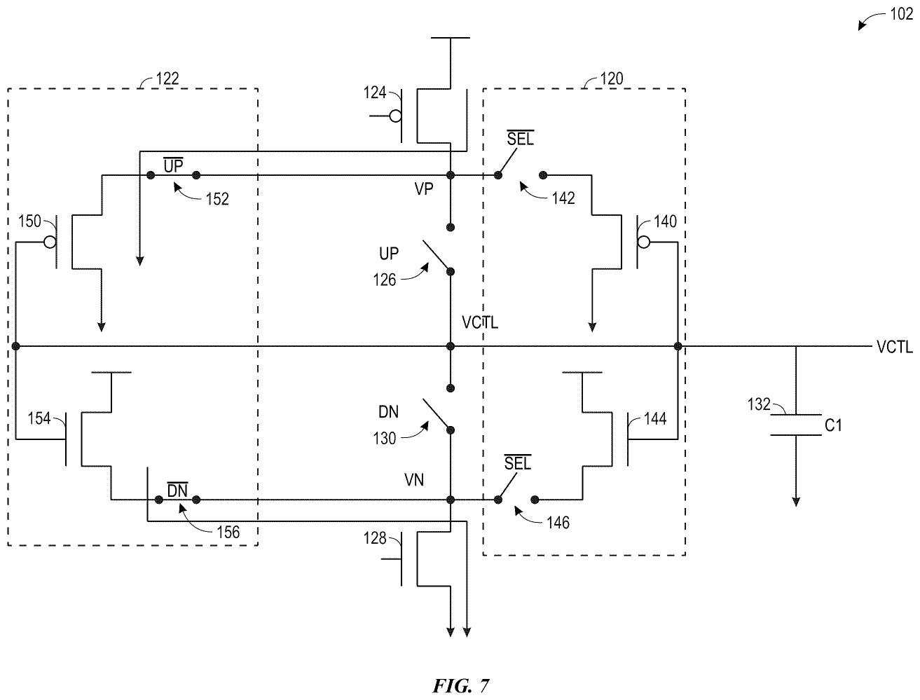

FIG. 7 is the schematic diagram of the charge pump 102 during an activated state, in accordance with embodiments of the present disclosure. In some cases, the device controller 84 may generate the selection signal with the first logic value discussed above to activate at least a portion (e.g., a slice) of the charge pump 102. In such cases, the first transistor 124 and the second transistor 128 may remain and/or switch on (e.g., activated) when the selection signal has the first logic value and/or the charge pump 102 is activated.

For example, the first transistor 124 may receive a first bias signal (e.g., a PMOS activation signal, a logic low signal) when the charge pump 102 is activated. Moreover, the second transistor 128 may receive a second bias signal (e.g., an NMOS activation signal, a logic high signal) when the charge pump 102 is activated. In some embodiments, the device controller 84 may generate the first bias signal and the second bias signal. In alternative or additional embodiments, the charge pump 102 may include circuitry (e.g., resources of the PLD 70 and/or the integrated circuit device 12, logic circuitry 26) to generate the first bias signal and the second bias signal based on the selection signal.

As mentioned above, the third switch 142 and the fourth switch 146 may receive an inverse of the selection signal (S̅E̅L̅). The third switch 142 and the fourth switch 146 may open in response to the charge pump 102 being activated and/or the selection signal having the first logic value. As such, the leakage reduction circuit may be deactivated in response to the charge pump 102 being activated and/or the selection signal having the first logic value.

The first switch 126 may receive the up signal UP when the charge pump 102 is activated and phases of the internal clock signal are lagging corresponding phases of the input clock signal. Moreover, the fifth switch 152 may receive an inverse of the up signal U̅P̅. As discussed above, the PFD 104 may generate the up signal UP based on whether phases of the internal clock signal are lagging corresponding phases of the input clock signal. In some embodiments, the PFD 104 discussed above may provide the up signal UP and the inverse of the up signal U̅P̅ to the charge pump 102. In alternative or additional embodiments, the charge pump 102 may include circuitry (e.g., an inverter, resources of the PLD 70, logic circuitry 26) to generate the inverse of the up signal U̅P̅ based on the up signal UP.

The first switch 126 may receive the up signal UP when the charge pump 102 is activated and phases of the internal clock signal are lagging corresponding phases of the input clock signal. The first switch 126 may close and couple the second terminal of the first transistor 124 to the filter capacitor 132 and/or the output terminal of the charge pump 102 in response to the up signal UP. As such, the first transistor 124 may supply electrical charges to the control voltage V_{CTL} to compensate for phase lag of the internal clock signal. Moreover, the fifth switch 152 may open in response to the first switch 126 receiving the up signal UP. As such, the fifth switch 152 may deactivate the fifth transistor 150 when the charge pump 102 is activated and phases of the internal clock signal are lagging corresponding phases of the input clock signal.

The PFD 104 may remove the up signal UP when the phases of the internal clock signal are not lagging corresponding phases of the input clock signal. The first switch 126 may open and uncouple the second terminal of the first transistor 124 from the filter capacitor 132 and/or the output terminal of the charge pump 102 in response to removing or not receiving the up signal UP. The fifth switch 152 may close and couple the first terminal of the fifth transistor 150 to the positive node V_{P} in response to the up signal UP being removed or not being received. The fifth transistor 150 may activate (e.g., switch on) and at least partially couple the positive node V_{P} of the charge pump 102 to the filter capacitor 132 and the output terminal of the charge pump 102. Accordingly, the static charge error reduction circuit 122 may become at least partially activated (or remain activated) when the charge pump 102 is activated and the up signal UP is removed.

The input terminal of the fifth transistor 150 may have a high input impedance above the high impedance threshold when the fifth transistor 150 is activated. Moreover, the first terminal of the fifth transistor 150 may have a low output impedance below the low impedance threshold when the fifth transistor 150 is activated. In some embodiments, the voltage of the first terminal of the first transistor 124 at the positive node V_{P} may be equal to (e.g., nearly equal to) a combination of a third threshold voltage V_{TP3} (e.g., a source-to-gate voltage) of the fifth transistor 150 and the control voltage V_{CTL} of the filter capacitor 132 at the output terminal:

$${V}_{P} ∼ = {V}_{CTL} + {V}_{TP 3} \qquad ( Equation 3 )$$

In some cases, a voltage value of the third threshold voltage V_{TP3} may be smaller (e.g., substantially smaller, relatively smaller) than the control voltage V_{CTL}. As such, the fifth transistor 150 may reduce a third differential voltage between the positive node V_{P} and the output terminal of the charge pump 102 when the charge pump 102 is activated and the first switch 126 is open.

Moreover, the static charge error reduction circuit 122 may reduce undesired accumulation of charges and/or a parasitic capacitance of the positive node V_{P} by reducing the third differential voltage. For example, when subsequently closing the first switch 126 to adjust the control voltage V_{CTL}, an adverse effect of the static charges and/or the parasitic capacitance of the positive node V_{P} may be reduced. As mentioned above, the VCO 106 may at least partially compensate for the phase lead or phase lag of the internal clock signal by adjusting charges and/or the voltage value of the control voltage V_{CTL}. Accordingly, the charge pump 102 may improve operations of the PLL 100 and/or the PLD 70 by reducing SPE and/or phase drift of the internal clock signal by including the fifth transistor 150.

The second switch 130 may receive the down signal DN when the charge pump 102 is activated and phases of the internal clock signal are leading corresponding phases of the input clock signal. Moreover, the sixth switch 156 may receive an inverse of the down signal D̅N̅. As discussed above, the PFD 104 may generate the down signal DN based on whether phases of the internal clock signal are leading corresponding phases of the input clock signal. In some embodiments, the PFD 104 discussed above may provide the down signal DN and the inverse of the down signal D̅N̅ to the charge pump 102. In alternative or additional embodiments, the charge pump 102 may include circuitry (e.g., an inverter, resources of the PLD 70, logic circuitry 26) to generate the inverse of the down signal DN based on the down signal DN.

The second switch 130 may receive the down signal DN when the charge pump 102 is activated and phases of the internal clock signal are leading corresponding phases of the input clock signal. The second switch 130 may close and couple the second terminal of the second transistor 128 to the filter capacitor 132 and/or the output terminal of the charge pump 102 in response to the down signal DN. As such, the second transistor 128 may sink or draw electrical charges from the control voltage V_{CTL} to compensate for phase lead of the internal clock signal. Moreover, the sixth switch 156 may open in response to the first switch 126 receiving the down signal DN. As such, the sixth switch 156 may deactivate the sixth transistor 154 when the charge pump 102 is activated and phases of the internal clock signal are leading corresponding phases of the input clock signal.

The PFD 104 may remove the down signal DN when the phases of the internal clock signal are not leading corresponding phases of the input clock signal. The second switch 130 may open and uncouple the second terminal of the second transistor 128 from the filter capacitor 132 and/or the output terminal of the charge pump 102 in response to removing or not receiving the down signal DN. The sixth switch 156 may close and couple the first terminal of the sixth transistor 154 to the negative node V_{N} in response to the down signal DN being removed or not being received.

The sixth transistor 154 may activate (e.g., switch on) and at least partially couple the negative node V_{N} of the charge pump 102 to the filter capacitor 132 and the output terminal of the charge pump 102. Accordingly, the static charge error reduction circuit 122 may become at least partially activated (or remain activated) when the charge pump 102 is activated and the down signal DN is removed. In some cases, the fifth transistor 150 and the sixth transistor 154 of the static charge error reduction circuit 122 may remain or switched on (e.g., be activated) simultaneously or during at least partially overlapping time periods when the charge pump 102 is activated.

The input terminal of the sixth transistor 154 may have a high input impedance above the high impedance threshold when the sixth transistor 154 is activated. Moreover, the first terminal of the sixth transistor 154 may have a low output impedance below the low impedance threshold when the sixth transistor 154 is activated. In some embodiments, the voltage of the first terminal of the second transistor 128 at the negative node V_{N} may be equal to (e.g., nearly equal to) a combination of a fourth threshold voltage V_{TP4} (e.g., a gate-to-source voltage) of the sixth transistor 154 and the control voltage V_{CTL} of the filter capacitor 132 at the output terminal:

$${V}_{N} ∼ = {V}_{CTL} - {V}_{TP 4} \qquad ( Equation 3 )$$

In some cases, a voltage value of the fourth threshold voltage V_{TP4} may be smaller (e.g., substantially smaller, relatively smaller) than the control voltage V_{CTL}. As such, the sixth transistor 154 may reduce a fourth differential voltage between the output terminal of the charge pump 102 and the negative node V_{N} when the charge pump 102 is activated and the second switch 130 is open.

Moreover, the static charge error reduction circuit 122 may reduce undesired accumulation of charges and/or a parasitic capacitance of the negative node V_{N} by reducing the fourth differential voltage. For example, when subsequently closing the second switch 130 to adjust the control voltage V_{CTL}, an adverse effect of the static charges and/or the parasitic capacitance of the negative node V_{N} may be reduced. As mentioned above, the VCO 106 may at least partially compensate for the phase lead or phase lag of the internal clock signal by adjusting charges and/or the voltage value of the control voltage V_{CTL}. Accordingly, the charge pump 102 may improve operations of the PLL 100 and/or the PLD 70 by reducing SPE and/or phase drift of the internal clock signal by including the sixth transistor 154.

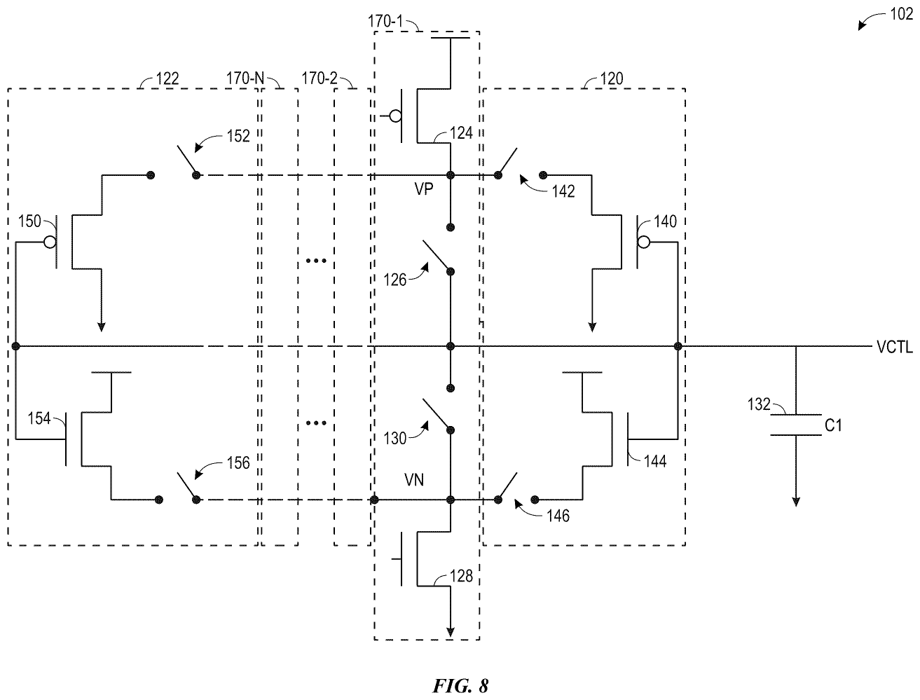

FIG. 8 is a block diagram of the charge pump 102 having multiple slices 170, in accordance with embodiments of the present disclosure. The charge pump 102 may include the leakage reduction circuit 120 and the static charge error reduction circuit 122 discussed above. In the depicted embodiment, a first slice 170-1, a second slice 170-2, and an Nth slice 170-N of the charge pump 102 may be coupled in parallel. As such, charges being supplied and/or sank or withdrawn by each of the slices 170-1 through 170-N may combine (e.g., cumulatively combine) at the filter capacitor 132 and/or the output terminal of the charge pump 102. It should be appreciated that in different embodiments, the charge pump 102 may include a different number of slices 170 (e.g., 1, 2, 3, and so on).

The first slice 170-1 of the charge pump 102 may include the first transistor 124, the first switch 126, the second transistor 128, and the second switch 130. The second slice 170-2 and the Nth slice 170-N of the charge pump 102 may include similar or different circuit components compared to the first slice 170-1. In some embodiments, the device controller 84 of the PLL 100 and/or the PLD 70 may generate a respective selection signal for activating each of the slices 170. Moreover, the device controller 84 may activate a number of the slices 170 to compensate for a phase lag or lead of the internal clock signal based on an electrical current, voltage, and/or clock frequency of the internal clock signal and/or the input clock signal, among other possibilities.

In some cases, the device controller 84 may store or access a stored lookup table to determine the number of slices 170 for compensating for a phase lag or lead of the internal clock signal. The lookup table may indicate a number of slices 170 based on a clock frequency of the internal clock signal, the input clock signal, and/or a divider ratio of the VCO 106 discussed above. As mentioned above, the charge pump 102 may generate the internal clock signal with multiple clock frequencies based on the input clock signal. For example, the device controller 84 may activate a higher number of the slices 170 to compensate for a phase lag or lead of the internal clock signal when clock frequency of the internal clock signal is higher.

In some embodiments, each slice 170 of the charge pump 102 may have a dedicated leakage reduction circuit 120 and a dedicated static charge error reduction circuit 122. In alternative or additional embodiments, each slice 170, or any viable combination of the slices 170 may share a respective leakage reduction circuit 120 and/or a respective static charge error reduction circuit 122. That is, the charge pump 102 may include any number of leakage reduction circuits 120 and/or static charge error reduction circuits 122 associated with multiple slice 170.

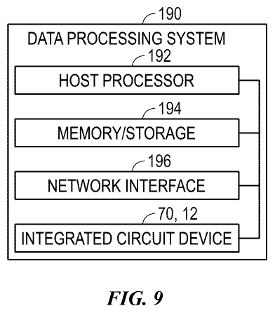

Bearing the foregoing in mind, the integrated circuit device 12 may be a component included in a data processing system, such as a data processing system 190, shown in FIG. 9. The data processing system 190 may include the integrated circuit device 12 (e.g., a programmable logic device), a host processor 192 (e.g., a processor), memory and/or storage circuitry 194, and a network interface 196. The data processing system 190 may include more or fewer components (e.g., electronic display, designer interface structures, ASICs). Moreover, any of the circuit components depicted in FIG. 9 may include integrated circuits (e.g., integrated circuit device 12).

The integrated circuit device may include the PLD 70. The host processor 192 may include any of the foregoing processors that may manage a data processing request for the data processing system 190 (e.g., to perform encryption, decryption, machine learning, video processing, voice recognition, image recognition, data compression, database search ranking, bioinformatics, network security pattern identification, spatial navigation, cryptocurrency operations, or the like). For example, the host processor 192 may include the device controller 84 of the PLL 100 and/or the PLD 70 discussed above.

The memory and/or storage circuitry 194 may include random access memory (RAM), read-only memory (ROM), one or more hard drives, flash memory, or the like. The memory and/or storage circuitry 194 may hold data to be processed by the data processing system 190. In some cases, the memory and/or storage circuitry 194 may also store configuration programs (bit streams) for programming the integrated circuit device 12. For example, the memory and/or storage circuitry 194 may store the lookup table storing values associated with a number of slices 170 of the charge pump 102 discussed above based on a clock frequency of the internal clock signal, the input clock signal, and/or the divider ratio.

The network interface 196 may allow the data processing system 190 to communicate with other electronic devices. The data processing system 190 may include several different packages or may be contained within a single package on a single package substrate. For example, components of the data processing system 190 may be located on several different packages at one location (e.g., a data center) or multiple locations. For instance, components of the data processing system 190 may be located in separate geographic locations or areas, such as cities, states, or countries.

In one example, the data processing system 190 may be part of a data center that processes a variety of different requests. For instance, the data processing system 190 may receive a data processing request via the network interface 196 to perform encryption, decryption, machine learning, video processing, voice recognition, image recognition, data compression, database search ranking, bioinformatics, network security pattern identification, spatial navigation, digital signal processing, or some other specialized task.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit device comprising:

What is claimed is:

1. A charge pump comprising:
a first transistor coupled to a supply voltage, wherein the first transistor is configured to supply electrical charges from the supply voltage to an output terminal of the charge pump via a first switch when activated; and
a first leakage reduction transistor coupled to the first transistor and the first switch, wherein the first leakage reduction transistor couples the first transistor to the output terminal when the first transistor is deactivated.

2. The charge pump of claim 1, comprising a first leakage reduction switch coupled to the first transistor and the first leakage reduction transistor, wherein the first leakage reduction switch is configured to uncouple the first transistor and the first leakage reduction transistor when the first transistor is activated.

3. The charge pump of claim 1, wherein the first transistor supplies electrical charges to the output terminal based on the first switch being closed.

4. The charge pump of claim 1, comprising a first static charge reduction transistor coupled to the first transistor, the first switch, and the first leakage reduction transistor, wherein the first static charge reduction transistor is configured to couple the first transistor to the output terminal when the first transistor is activated and the first switch is open.

5. The charge pump of claim 1, comprising a second transistor coupled to a ground terminal, wherein the second transistor is configured to sink electrical charges from the output terminal to the ground terminal via a second switch when activated.

6. The charge pump of claim 5, comprising a second leakage reduction transistor coupled to the second transistor and the second switch, wherein the second leakage reduction transistor couples the second transistor to the output terminal when the second transistor is deactivated.

7. The charge pump of claim 6, comprising a second leakage reduction switch coupled to the second transistor and the second leakage reduction transistor, wherein the second leakage reduction switch is configured to uncouple the second transistor and the second leakage reduction transistor when the second transistor is activated.

8. The charge pump of claim 5, comprising a second static charge reduction transistor coupled to the second transistor and the second switch, wherein the second static charge reduction transistor is configured to couple the second transistor to the output terminal when the second transistor is activated and the second switch is open.

9. A programmable logic device comprising:
a voltage-controlled oscillator (VCO) configured to generate an internal clock signal based on an input clock signal and a control voltage; and
a charge pump coupled to the VCO, wherein the charge pump comprises:
a first transistor configured to increase the control voltage via a first switch when activated; and
a first leakage reduction transistor coupled to the first transistor and the first switch, wherein the first leakage reduction transistor provides the control voltage to the first transistor when the first transistor is deactivated.

10. The programmable logic device of claim 9, comprising a phase-frequency detector (PFD 104) coupled to the VCO and the charge pump, wherein the PFD is configured to:
receive the input clock signal and the internal clock signal; and
generate a first signal in response to a phase of the internal clock signal lagging a corresponding phase of the input clock signal.

11. The programmable logic device of claim 10, wherein the first switch is configured to couple the first transistor to the VCO based on the first signal.

12. The programmable logic device of claim 9, wherein the VCO is configured to divide the input clock signal based on a divider ratio to generate the input clock signal.

13. The programmable logic device of claim 9, wherein the charge pump comprises a first static charge reduction transistor coupled to the first transistor, the first switch, and the first leakage reduction transistor, wherein the first static charge reduction transistor provides the control voltage to the first transistor when the first transistor is activated and the first switch is open.

14. The programmable logic device of claim 9, wherein the charge pump comprises:
a second transistor configured to decrease the control voltage via a second switch when activated; and
a second leakage reduction transistor coupled to the second transistor and the second switch, wherein the second leakage reduction transistor provides the control voltage to the second transistor when the second transistor is deactivated.

15. The programmable logic device of claim 14, wherein the charge pump comprises a second static charge reduction transistor coupled to the second transistor, the second switch, and the second leakage reduction transistor, wherein the second static charge reduction transistor provides the control voltage to the second transistor when the second transistor is activated and the second switch is open.

16. A data processing system comprising:
a device controller configured to generate a selection signal; and
a programmable logic device coupled to the device controller, wherein the programmable logic device comprises:
a voltage-controlled oscillator (VCO) configured to generate an internal clock signal based on an input clock signal and a control voltage; and
a charge pump coupled to the VCO, wherein the charge pump comprises:
a first transistor configured to increase the control voltage via a first switch based on the selection signal having a first logic value;
a first leakage reduction transistor coupled to the first transistor and the first switch, wherein the first leakage reduction transistor provides the control voltage to the first transistor based on the selection signal having a second logic value; and
a first static charge reduction transistor coupled to the first transistor, the first switch, and the first leakage reduction transistor, wherein the first static charge reduction transistor provides the control voltage to the first transistor based on the selection signal having the second logic value.

17. The data processing system of claim 16, wherein the charge pump comprises:
a second transistor configured to decrease the control voltage via a second switch based on the selection signal having the first logic value; and
a second leakage reduction transistor coupled to the second transistor and the second switch, wherein the second leakage reduction transistor provides the control voltage to the second transistor based on the selection signal having the second logic value.

18. The data processing system of claim 17, wherein the charge pump comprises a second static charge reduction transistor coupled to the second transistor, the second switch, and the second leakage reduction transistor, wherein the second static charge reduction transistor provides the control voltage to the second transistor based on the selection signal having the second logic value.

19. The data processing system of claim 16, wherein the device controller is configured to generate a signal indicative of a divider ratio, wherein the VCO is configured to generate the internal clock signal with a clock frequency based on the divider ratio.

20. The data processing system of claim 16, wherein the programmable logic device comprises a field programmable logic device comprising the VCO or the charge pump.
